(19) United States
(12) Patent Application Publication
(10) Pub. No.: US 2026/0328806 A1
(43) Pub. Date: Oct. 22, 2026

(54) CARRIER FOR SEMICONDUCTOR PRODUCT

(71) Applicant: ATECO INC., Gunpo-si (KR)

(72) Inventors: Taek Seon LEE, Hwaseong-si (KR); Ho Nam KIM, Seongnam-si (KR); Sung Chul MOON, Gunpo-si (KR); Han Su BAE, Siheung-si (KR); Ji Eun SON, Anyang-si (KR)

(21) Appl. No.: 19/642,373

(22) Filed: Apr. 8, 2026

(30) Foreign Application Priority Data
Apr. 17, 2025 (KR) 10-2025-0050401
Mar. 13, 2026 (KR) 10-2026-0045479

(51) Int. Cl. G01R 1/04; G01R 31/28

(52) U.S. Cl. CPC G01R 1/0466; G01R 31/2863

(57) ABSTRACT

A carrier for a fine-pitch semiconductor product according to an embodiment of the present disclosure comprises: an insert body providing a loading space in which a semiconductor product may be accommodated; a precision-contact interposer defining a bottom of the loading space, wherein the precision-contact interposer may have a plurality of upper terminals and a plurality of lower terminals electrically connected to the upper terminals, wherein a spacing between the lower terminals may be larger than a spacing between the upper terminal; and a socket contacting part positioned under the precision-contact interposer, wherein the socket contacting part in lieu of the precision-contact interposer may be brought into close contact with a socket of a test apparatus, wherein the socket contacting part may have a plurality of contact terminals electrically connecting contact points of the socket with the lower terminals.

### CROSS REFERENCE TO RELATED APPLICATIONS

Priority to Korean patent application number 10-2025-0050401 filed on Apr. 17, 2025, and Korean patent application number 10-2026-0045479 filed on Mar. 13, 2026, the entire disclosure of which is incorporated by reference herein, is claimed.

### TECHNICAL FIELD

The present disclosure relates to a carrier for a semiconductor product, and more particularly, to a carrier for a fine-pitch semiconductor product. This work was supported by the Technology development Program (RS-2024-00487757) funded by the Ministry of SMEs and Startups (MSS, Korea)

### BACKGROUND

In general, semiconductor products are mounted on a test apparatus having a motherboard before being supplied to the market, and subjected to a performance test. Such testing is referred to as a mounting test, so-called because the semiconductor product is actually mounted and tested. Semiconductor products classified as non-defective as a result of the mounting test are supplied to the market, while those classified as defective are filtered out and discarded.

In addition, semiconductor products may exist in various forms depending on the package level. In general, the package level of a semiconductor product is classified into four levels. First, a zero-th level semiconductor product is in the form of a chip or die obtained by cutting a wafer. A first-level semiconductor product is in the form of a single chip module in which a chip is packaged as a single product. A second-level semiconductor product is in the form of a module in which the first-level semiconductor product is mounted on a card or the like. Finally, a third-level semiconductor product is in the form of a motherboard on which the second-level semiconductor product is mounted.

In this regard, conventional mounting tests were often performed on semiconductor products of the second level or higher, in consideration of testing efficiency. However, with the recent trend toward higher-performance devices, the need for mounting tests targeting zero-th level to first-level products is increasing. However, such low-level semiconductor products have very small terminal sizes and are arranged in a fine pitch, making it difficult to perform mounting tests with automated equipment. This is because the characteristics of low-level semiconductor products increase the difficulty of aligning the semiconductor product with the socket of the test apparatus. In addition, since low-level semiconductor products are vulnerable to external forces and may be easily damaged during the mounting test process, considerably more care is required during transport and testing compared to high-level semiconductor products.

### SUMMARY

A problem to be solved by the present disclosure is to provide a carrier that helps to conveniently transport and mounting-test a low-level semiconductor product.

The problems of the present disclosure are not limited to the aforementioned problems, and other problems not mentioned will be clearly understood by those skilled in the art from the description below.

A carrier for a fine-pitch semiconductor product according to an embodiment of the present disclosure for solving the above problems comprises: an insert body providing a loading space in which a semiconductor product may be accommodated; a precision-contact interposer defining a bottom of the loading space, wherein the precision-contact interposer may have a plurality of upper terminals upwardly exposed from an upper surface thereof so as to be in contact with device terminals of the semiconductor product accommodated in the loading space, and a plurality of lower terminals electrically connected to the upper terminals and downwardly exposed from a lower surface thereof, wherein a spacing between the lower terminals may be larger than a spacing between the upper terminal; and a socket contacting part positioned under the precision-contact interposer, wherein the socket contacting part in lieu of the precision-contact interposer may be brought into close contact with a socket of a test apparatus, wherein the socket contacting part may have a plurality of contact terminals electrically connecting contact points of the socket with the lower terminals, respectively.

The precision-contact interposer may comprise a circuit board having the lower terminals formed on a lower surface thereof and the upper terminals formed on an upper surface thereof, wherein the upper terminals may have minute sizes and arrangement spacings corresponding to minute sizes and arrangement spacings of the device terminals.

The precision-contact interposer further may comprise a cover pad disposed on top of the circuit board so as to protect the device terminals and the circuit board during a process of bringing the semiconductor product and the circuit board into contact with each other, wherein the cover pad may include an elastic material and may have a plurality of pad holes extending therethrough to expose the upper terminals.

The precision-contact interposer further may comprise a guide film disposed on top of the cover pad and having guide holes formed therein and aligned above the pad holes, wherein the guide film may include an elastic material and thus may guide the device terminals approaching the circuit board toward the pad holes base on an elastic force.

The precision-contact interposer further may comprise a cover pad disposed on top of the circuit board so as to protect the device terminals and the circuit board during a process of bringing the semiconductor product and the circuit board into contact with each other, wherein the cover pad may include an elastic material and may have conductive materials respectively disposed between the upper terminals and the device terminals.

An observation hole extending through the precision-contact interposer and the socket contacting part may be formed to observe the semiconductor product accommodated in the loading space.

The precision-contact interposer may be constructed so as to be replaceable separately from the socket contacting part so that a plurality types of semiconductor products can be tested using a single test apparatus.

The carrier for a fine-pitch semiconductor product may further comprise a guide member mounted to the insert body in a horizontally reciprocating manner so as to laterally push the semiconductor product accommodated in the loading space.

The guide member may be mounted to the insert body such that at least a portion thereof can move toward or away from a side wall of the insert body.

The guide member may be formed in a shape capable of contacting two surfaces of the semiconductor product meeting each other in a process of pushing the semiconductor product.

The device terminals and the upper terminals may be aligned with each other in a state in which the guide member may have pushed the semiconductor product accommodated in the loading space to a maximum extent.

The carrier for a fine-pitch semiconductor product may further comprise an open-maintaining elastic member constructed to provide an elastic force to the guide member such that the guide member moves away from the loading space; and a pressing member constructed to receive an external force to move toward the guide member to overcome the elastic force of the open-maintaining elastic member to move the guide member toward the loading space.

The insert body may comprise: a lower body to which the precision-contact interposer and the socket contacting part are coupled; and an upper body coupled to an upper side of the lower body in a liftable manner, wherein the upper body surrounds the loading space, and may have an open upper surface.

The pressing member may be connected to the upper body and may be constructed to move the guide member toward the loading space while the pressing member moves vertically together with the upper body.

The carrier for a fine-pitch semiconductor product may further comprise a fixing latch having one end coupled to the lower body in an angle-adjustable manner, and constructed such that an angle thereof may be adjusted along with the upper body moving vertically, wherein in a state in which the upper body has been maximally raised, the other end of the fixing latch downwardly presses the semiconductor product accommodated in the loading space while being positioned on top of the semiconductor product.

While the upper body is descending, the pressing member retracts downwards while being positioned in rear of the guide member, wherein while the upper body may be ascending, the pressing member moves upwardly to move the guide member toward the loading space while being positioned in rear of the guide member.

The carrier for a fine-pitch semiconductor product may further comprise a fixing latch coupled to the insert body in an angle-adjustable manner to selectively fix the semiconductor product accommodated in the loading space.

The fixing latch may comprise: a pivotable link having one end coupled to the insert body in an angle-adjustable manner; and a fixing member constructed to selectively press the semiconductor product based on the angle of the pivotable link, wherein the fixing member may be coupled to the other end of the pivotable link in an angle-adjustable manner.

The fixing latch further may comprise a fixing elastic member constructed to provide an elastic force acting toward the semiconductor product to the fixing member in a state in which the fixing member may be in contact with the semiconductor product.

The carrier for a fine-pitch semiconductor product may further comprise a contact pusher removably mounted onto an upper side of the insert body, wherein in a mounted state thereon, the contact pusher presses the fixing member downwards.

The fixing latch may include a pair of fixing latches coupled to the insert body and facing each other, wherein an end portion of the fixing member may be concavely recessed so that, in a state in which the pair of fixing latches may have fixed the semiconductor product, a central area of the semiconductor product may be exposed to an outside.

Other specific details of the present disclosure are included in the detailed description and drawings.

### ADVANTAGEOUS EFFECTS

According to the embodiments of the present disclosure, at least the following effects are achieved.

The efficiency of mounting-test the low-level semiconductor products may be maximized.

The effects according to the present disclosure are not limited by the content exemplified above, and more various effects are included herein.

### BRIEF DESCRIPTION OF THE DRAWINGS

FIG. 1 is a drawing representing a carrier for a semiconductor product according to an embodiment of the present disclosure.

FIG. 2 is an exploded perspective view of the carrier shown in FIG. 1.

FIG. 3 is a drawing for illustrating the stacked structure of a precision-contact interposer and a socket contacting part according to an embodiment of the present disclosure.

FIG. 4 is a drawing illustrating a contact pusher according to an embodiment of the present disclosure.

FIG. 5 is a drawing representing a locked state of a carrier according to an embodiment of the present disclosure.

FIG. 6 is a drawing representing an open state of a carrier according to an embodiment of the present disclosure.

FIG. 7 is a cross-sectional view representing a cross-section of the carrier cut along the A-A' cutting line indicated in FIG. 5 in a state in which a semiconductor product is loaded in the carrier.

FIG. 8 is a drawing for illustrating a socket in which a carrier according to an embodiment of the present disclosure is seated.

FIG. 9 is a cross-sectional view of a state in which a mounting test is performed using a carrier according to an embodiment of the present disclosure.

FIG. 10 is a drawing conceptually representing a state in which a mounting test is performed using a carrier according to an embodiment of the present disclosure.

FIG. 11 is a drawing illustrating a guide member according to an embodiment of the present disclosure.

FIG. 12 is a drawing representing a state in which a guide member according to an embodiment of the present disclosure is accommodated to a maximum extent inside the insert body.

FIG. 13 is a drawing representing a state in which a guide member according to an embodiment of the present disclosure protrudes to a maximum extent outside the insert body.

FIG. 14 is a drawing representing the state of the guide member in the same state as FIG. 12.

FIG. 15 is a drawing representing the state of the guide member in the same state as FIG. 13.

### DETAILED DESCRIPTION

The advantages and features of the present disclosure, and the methods for achieving them, will be clarified with reference to the embodiments described in detail below taken together with the accompanying drawings. However, the present disclosure is not limited to the embodiments disclosed below, but may be implemented in various different forms. The present embodiments are provided merely to make the disclosure of the present disclosure complete and to fully inform those skilled in the art of the scope of the disclosure, and the present disclosure is defined only by the scope of the claims.

In addition, the embodiments described herein will be described with reference to cross-sectional views and/or schematic diagrams that are ideal exemplary views of the present disclosure. Therefore, the forms of the exemplary views may be modified due to manufacturing techniques and/or tolerances. In addition, each of the components shown in each drawing of the present disclosure may be shown somewhat enlarged or reduced for convenience of illustration. The same reference numerals refer to the same components throughout the specification.

Directions such as upper, lower, front, rear, left, or right mentioned hereinafter are merely described with one direction as a reference for convenience of illustration, and the present disclosure is not limited to the described direction. That is, it is obvious that in the actual installation and use process of the present disclosure, the direction may be changed to a different direction from the description below, and the present disclosure should be construed to include such embodiments.

The "semiconductor product" mentioned below may generally refer to a semiconductor product packaged at the first level to the second level. However, the present disclosure is not necessarily limited to such examples, and while maintaining the core features of the present disclosure, it may also be applicable to semiconductor products packaged at the third to fourth level with some modifications.

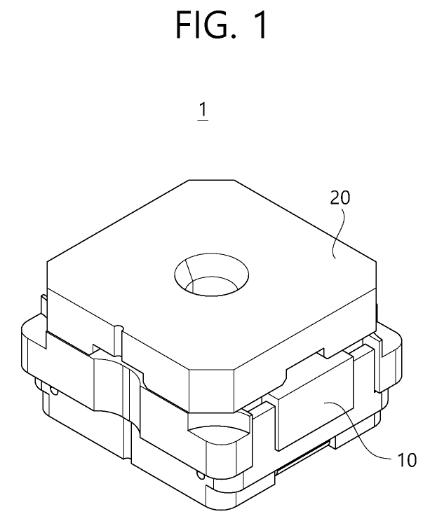

Hereinafter, the present disclosure will be described with reference to the drawings for illustrating a carrier for a semiconductor product according to an embodiment of the present disclosure. FIG. 1 is a drawing representing a carrier for a semiconductor product according to an embodiment of the present disclosure.

As shown in FIG. 1, a carrier 1 according to an embodiment of the present disclosure may include an insert 10 and a contact pusher 20. First, the insert 10 is formed to be capable of loading a semiconductor product to be tested. A plurality of inserts 10 may be mounted on a tray and transported all at once. For example, a tray on which the inserts 10 are mounted may have grooves for mounting the insert 10 at each position where an insert 10 is to be mounted. The technology of mounting the insert 10 on a tray and loading it onto the test apparatus corresponds to technology already known in the industry related to mounting tests, and thus its description is omitted.

The contact pusher 20 may be a cover inserted into the upper portion of the insert 10. In this regard, FIG. 1 illustrates an example in which the contact pusher 20 is inserted into the upper portion of the insert 10; however, the contact pusher 20 may also be implemented as a component of a separate device rather than as a component of the carrier 1. For example, the contact pusher 20 may be mounted on the lower end of a device that presses down on the insert 10 from above when the tray is seated in the test apparatus. However, for convenience of illustration, the following description is based on an embodiment in which the contact pusher 20 is implemented in the form of a lid mounted on the upper portion of the insert

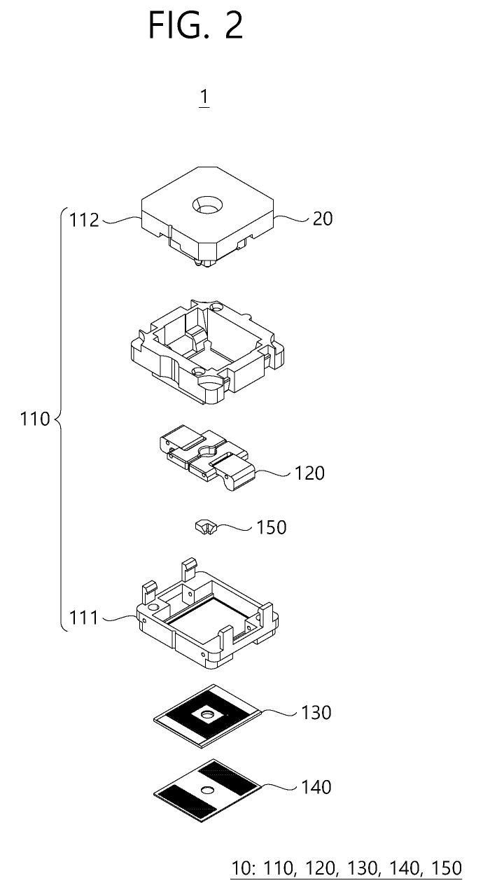

Hereinafter, with reference to FIG. 2, the configuration of the carrier 1 according to an embodiment of the present disclosure is described in detail. FIG. 2 is an exploded perspective view of the carrier shown in FIG. 1.

As shown in FIG. 2, the insert 10 may include an insert body 110, a fixing latch 120, a precision-contact interposer 130, a socket contacting part 140, and a guide member 150.

The insert body 110 is formed to provide a loading space in which a semiconductor product is accommodated. In some cases, the loading space may be referred to as a pocket in which the semiconductor product is accommodated. The insert body 110 is provided in a shape that may be mounted on a tray, and the overall shape may be similar to a rectangular wall surrounding the loading space. In this regard, the upper surface of the insert body 110 is open, and the center of the lower surface may be penetrated. Accordingly, in a state in which the precision-contact interposer 130 and the socket contacting part 140 are mounted on the lower surface of the insert body 110, the insert 10 may have a general shape similar to a box having an open top.

The insert body 110 may be further divided into a lower body 111 and an upper body 112.

The lower body 111 is provided in a shape in which the center is hollow, and has a structure in which the upper end may be coupled to the upper body 112. In addition, the lower end of the lower body 111 is formed to have a structure for mounting the precision-contact interposer 130 and the socket contacting part 140. The lower body 111 has a structure surrounding the lower end of the loading space, and when a semiconductor product is loaded into the insert 10, it is loaded at a position toward the center side of the lower body 111.

The upper body 112 is coupled to the upper side of the lower body 111. The upper surface of the upper body 112 is open so that conventionally known transport equipment such as a picker may transfer the semiconductor product to the inside of the insert 10. The upper body 112 may be formed to surround most of the loading space. According to the embodiment, the upper body 112 may be coupled to the lower body 111 in a liftable manner. In the following, for convenience of description, the example in which the upper body 112 is coupled to the lower body 111 so as to be elevated is described; however, the present disclosure is not necessarily limited to such an embodiment. For example, the upper body 112 may also be fixed without moving while coupled to the lower body 111.

The fixing latch 120 is coupled to the insert body 110 in an angle-adjustable manner and selectively fixes the semiconductor product accommodated in the loading space. For example, the fixing latch 120 may be provided as a pair facing each other, to press the semiconductor product together from above and fix it. More specifically, the fixing latch 120 may be coupled to the lower body 111 in an angle-adjustable manner. The semiconductor product seated on the precision-contact interposer 130, in a state in which the free end of the fixing latch 120 is rotated toward the bottom of the loading space, is pressed downward by the fixing latch 120 and its position is fixed.

When the upper body 112 is coupled to the lower body 111 so that the height can be adjusted, the fixing latch 120 has a structure in which its angle with respect to the lower body 111 changes according to the height adjustment of the upper body 112. Specifically, the fixing latch 120 may be connected to the upper body 112 such that, when the upper body 112 is maximally raised, the free end is in a state of pressing the semiconductor product accommodated in the loading space from above. In this case, as the upper body 112 descends, the free end of the fixing latch 120 rotates upward, and the fixing of the semiconductor product is released. For convenience of illustration, hereinafter, the state in which the fixing latch 120 fixes the semiconductor product is referred to as a "locked state," and the state in which the fixing latch 120 is bent upward to the maximum extent (the state in which it is brought into maximum contact with the side wall of the insert) is referred to as an "open state." In this regard, in the above-mentioned embodiment in which the upper body 112 is fixed to the lower body 111, a separate device may be used for switching the state of the fixing latch 120.

The precision-contact interposer 130 constitutes the bottom of the loading space and supports the semiconductor product accommodated in the loading space. The precision-contact interposer 130 has upper terminals exposed on the upper surface and lower terminals exposed on the lower surface. In this case, the upper terminals and the lower terminals are electrically connected to each other. In addition, the size of the lower terminals may be larger than the size of the upper terminals. In addition, the spacing of the lower terminals may be wider than the spacing of the upper terminals. Here, the upper terminals are terminals for contacting the terminals formed on the semiconductor product (hereinafter, device terminals). In addition, the lower terminals are terminals for being electrically connected to the socket contacting part 140. The upper terminals and the lower terminals may be composed of a conventionally known conductive material, and their form is not limited.

The socket contacting part 140 prevents the precision-contact interposer 130 from directly contacting the test apparatus. The socket contacting part 140 is configured to reinforce the rigidity of the precision-contact interposer 130 and prevent damage to the precision-contact interposer 130. At the same time, the socket contacting part 140 electrically connects the socket and the precision-contact interposer 130 for testing. That is, the socket contacting part 140 contacts the socket in lieu of the precision-contact interposer 130, and serves the role of electrically connecting the precision-contact interposer 130 to the socket. To perform this role, the socket contacting part 140 has contact terminals that contact the lower terminals. The contact terminals may be composed of a conductive material, similar to the lower terminals. In a state in which the socket contacting part 140 is seated in the socket, the semiconductor product is electrically connected to the socket through the precision-contact interposer 130 and the socket contacting part 140.

The guide member 150 is configured to guide the position at which the semiconductor product is seated during the process of the semiconductor product being accommodated in the loading space. The guide member 150 is mounted to the insert body 110 in a horizontally reciprocating manner, so as to push the semiconductor product from the side. In this regard, the guide member 150 may be disposed in the gap between the upper body 112 and the lower body 111 in a state in which the upper body 112 and the lower body 111 are coupled. A detailed description of the guide member 150 will be provided below.

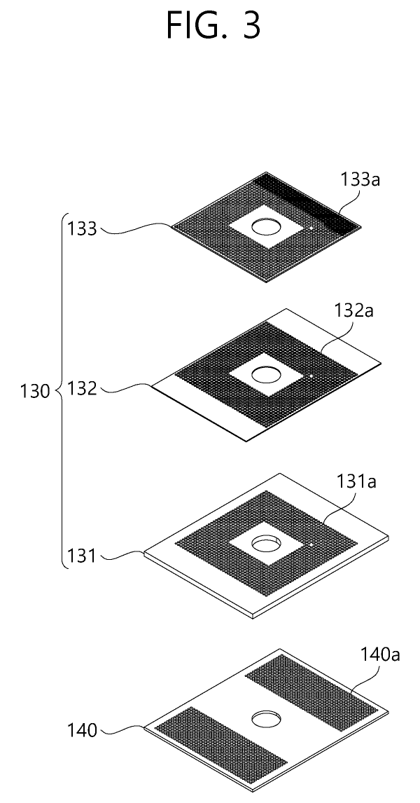

Hereinafter, with reference to FIG. 3, the precision-contact interposer 130 and the socket contacting part 140 according to an embodiment of the present disclosure are described in detail. FIG. 3 is a drawing for illustrating the stacked structure of a precision-contact interposer and a socket contacting part according to an embodiment of the present disclosure.

As shown in FIG. 3, the precision-contact interposer 130 may be divided into a circuit board 131, a cover pad 132, and a guide film 133. In this regard, as shown in FIG. 3, the circuit board 131, the cover pad 132, the guide film 133, and the socket contacting part 140 may each be formed in approximately a rectangular plate or film shape. In addition, from the bottom up, the socket contacting part 140, the circuit board 131, the cover pad 132, and the guide film 133 may be stacked in this order.

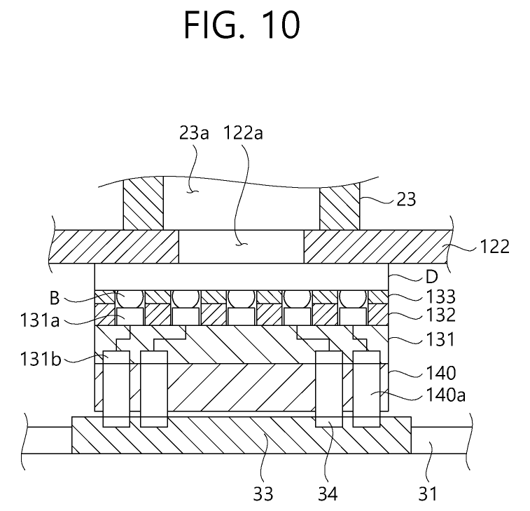

The circuit board 131 is a board on which lower terminals 131b (see FIG. 10) are formed on the lower surface and upper terminals 131a are formed on the upper surface. In order to correspond to the minute size and arrangement spacing of device terminals, the precision-contact interposer 130 according to an embodiment of the present disclosure implements the contact structure with the semiconductor product using the circuit board 131.

As one example, the circuit board 131 may be formed based on a glass substrate. This is because, when a glass substrate is used, it is easy to implement fine circuitry and may have excellent heat resistance. However, the circuit board 131 according to the embodiment of the present disclosure is not necessarily composed based on a glass substrate, and may also be designed based on other conventionally known technologies capable of implementing precision circuitry. For example, the circuit board 131 may also be designed using other conventionally known boards for wiring, such as a PCB (Printed Circuit Board) including a thermosetting resin, or a PCB including a ceramic material.

Accordingly, the precision-contact interposer 130 according to the present disclosure has the advantage of being capable of forming a circuit structure that may contact even fine-pitch semiconductor products. At the same time, the precision-contact interposer 130 according to the present disclosure may have the characteristic of being resistant to heat generated during the mounting test when using a glass substrate or the like with high heat resistance.

In this regard, the lower terminals 131b on the lower surface of the circuit board 131 are arranged at a wider spacing compared to the upper terminals 131a exposed on the upper surface of the circuit board 131. Specifically, when the circuit board 131 is seated on the socket contacting part 140 in alignment therewith, the lower terminals 131b are positioned at positions that overlap with the contact terminals 140a. This has the advantage of reducing the difficulty of the work of aligning the socket with the insert after the semiconductor product has once been seated in the correct position in the insert. That is, since the size and spacing of the lower terminals 131b are larger than those of the upper terminals 131a, the allowable tolerance of the work of aligning the socket with the insert is larger than the allowable tolerance of the work of loading the semiconductor product into the insert. Accordingly, even if a plurality of inserts are seated on their corresponding sockets all at once as a tray, it is easy to properly contact all inserts with the sockets.

The cover pad 132 is an intermediate layer for protecting the device terminals and the circuit board 131 during the process of the semiconductor product coming into contact with the circuit board 131. The cover pad 132 covers the upper surface of the circuit board 131 and has pad holes 132a extending therethrough to expose the upper terminals 131a. The cover pad 132 is formed based on an elastic material, and absorbs a portion of the impact generated during the process of the semiconductor product being brought into close contact with the circuit board 131, thereby protecting the semiconductor product and the circuit board 131. As one example, the cover pad 132 may be formed based on rubber.

In this regard, in the description above, the embodiment in which pad holes 132a penetrate through the cover pad 132 has been described; however, the cover pad 132 may also be implemented in the form of a rubber socket in which, instead of having the pad holes 132a extending through, a conductive material is arranged at the positions of the pad holes 132a. In this case, since the device terminals are electrically connected to the upper terminals 131a through the cover pad 132, the performance of preventing damage to the circuit board 131 and the device terminals is further enhanced. However, in the following, for convenience of illustration, the embodiment in which the pad holes 132a are formed is mainly described; the cover pad 132 in which a conductive material is arranged instead of the pad holes 132a may also function in the same manner as the embodiment in which the pad holes 132a are formed.

The guide film 133 covers the upper surface of the cover pad 132 and has guide holes 133a extending therethrough aligned above the pad holes 132a. The guide film 133 includes an elastic material and may guide the device terminals approaching the circuit board 131 toward the pad holes 132a based on elastic force. Specifically, if the device terminals slightly deviate when entering the guide holes 133a, the guide film 133 becomes folded. In this regard, the restoring force acting on the guide film 133 pushes away the device terminals, thereby causing the device terminals to be aligned with the pad holes 132a. Such a guide film 133 may be provided as, for example, a PI film.

The socket contacting part 140 is stacked below the circuit board 131 and has contact terminals 140a in contact with the lower terminals 131b (see FIG. 10). In addition, the contact terminals 140a exposed on the lower surface of the socket contacting part 140 have a spacing corresponding to the contact points of the socket of the test apparatus. Therefore, the lower terminals 131b may be electrically connected to the socket through the contact terminals 140a. In this regard, in FIG. 3, the contact terminals 140a are illustrated as extending in a straight line in the height direction; however, similar to the circuit board 131, it is also possible that the pitch between the contact terminals 140a becomes wider on the lower surface compared to the upper surface of the socket contacting part 140.

In this regard, the precision-contact interposer 130 may be replaceable separately from the socket contacting part 140. Specifically, the precision-contact interposer 130 may be custom-manufactured according to the semiconductor product and replaced depending on the type of semiconductor product to be tested. In this case, the upper terminals 131a may have different spacings in different precision-contact interposers 130, but the lower terminals 131b may always have the same or similar spacing. Accordingly, according to the present disclosure, only the precision-contact interposer 130 needs to be replaced depending on the semiconductor product to be tested, enabling a single test apparatus to test a plurality of different semiconductor products.

In this regard, through-holes aligned in a row are formed in the center portions of the socket contacting part 140, the circuit board 131, the cover pad 132, and the guide film 133. A single hole formed by the through-holes in a state in which the socket contacting part 140, the circuit board 131, the cover pad 132, and the guide film 133 are stacked is referred to as an observation hole. The observation hole may be formed to observe the semiconductor product accommodated in the loading space from the outside.

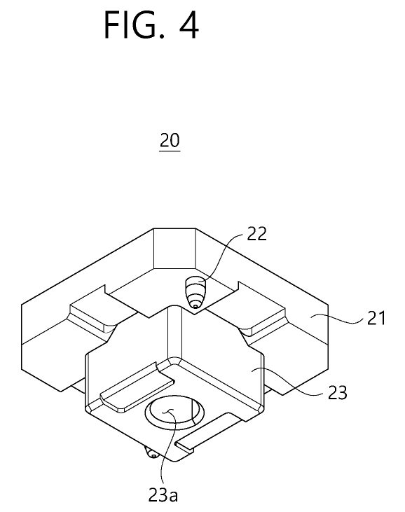

Hereinafter, with reference to FIG. 4, the contact pusher according to an embodiment of the present disclosure is described. FIG. 4 is a drawing illustrating a contact pusher according to an embodiment of the present disclosure.

As shown in FIG. 4, the contact pusher 20 according to an embodiment of the present disclosure may be divided into a cover plate 21 and a pressing protrusion 23.

The cover plate 21 may be a plate-shaped member having a shape that covers the upper body. At least one insertion pin 22 may protrude from the lower surface of the cover plate 21. When the contact pusher 20 is configured as the end portion of a device that presses the insert from above, the insertion pin 22 serves as an alignment pin that adjusts the position of the insert relative to the tray. In contrast, when the contact pusher 20 is detachably mounted to the insert body, the insertion pin 22 may be a pin for fixing the contact pusher 20 to the insert body.

The pressing protrusion 23 is formed similarly to a column protruding downward from the center of the cover plate 21. During the process of the cover plate 21 being seated on the upper surface of the insert body, the pressing protrusion 23 enters the interior of the loading space and presses the fixing latch downward. That is, the pressing protrusion 23 presses the fixing latch to indirectly press the semiconductor product downward. At the center of the pressing protrusion 23, a gas passage 23a through which gas flows for adjusting the temperature of the semiconductor product during the mounting test may extend through. The gas passage 23a may be formed penetrating the pressing protrusion 23 and the cover plate 21 along the central axis of the contact pusher 20 extending in the height direction.

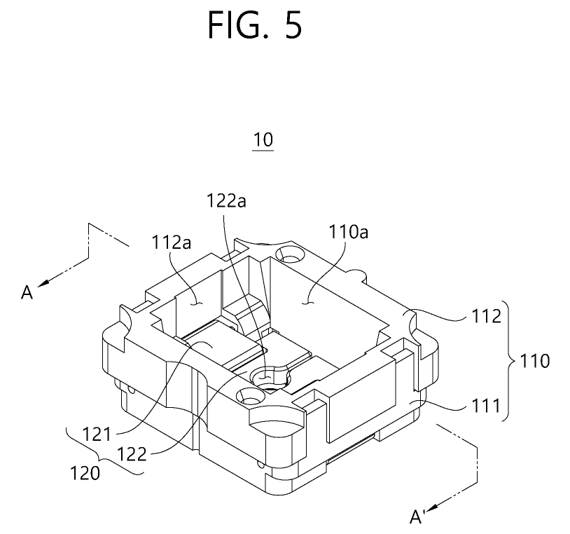

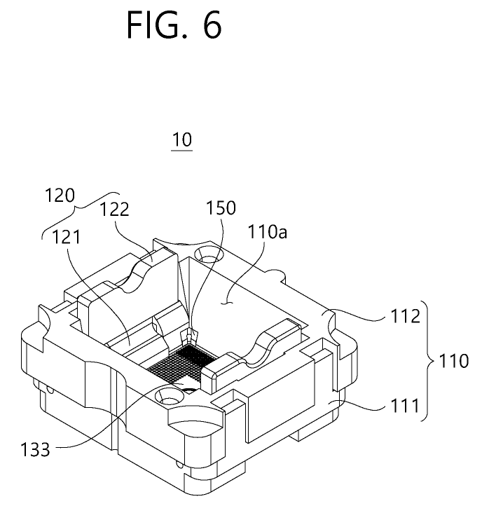

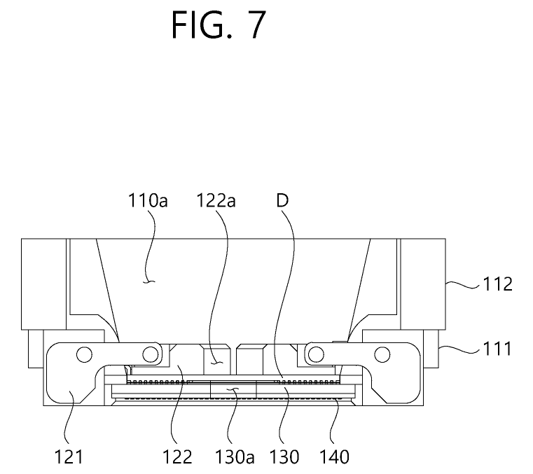

Hereinafter, with reference to FIGS. 5, 6, and 7, the state-switching structure of the carrier according to an embodiment of the present disclosure is described in detail. FIG. 5 is a drawing representing a locked state of a carrier according to an embodiment of the present disclosure. In contrast, FIG. 6 is a drawing representing an open state of a carrier according to an embodiment of the present disclosure. In addition, FIG. 7 is a cross-sectional view representing a cross-section of the carrier cut along the A-A' cutting line indicated in FIG. 5 in a state in which a semiconductor product is loaded in the carrier.

Referring to FIGS. 5 to 7, the fixing latch 120 according to an embodiment of the present disclosure may include a pivotable link 121 and a fixing member 122.

The pivotable link 121 is a rod-shaped or flat plate-shaped member having one end coupled to the lower body 111 in an angle-adjustable manner. For example, a link hole into which a first shaft member functioning as a rotation axis may be inserted may extend through one end of the pivotable link 121. In this case, the first shaft member inserted into the link hole is mounted to the lower body 111, so that the pivotable link 121 may be rotatably coupled to the lower body 111. As another example, a first shaft member functioning as a rotation axis may protrude in both directions from one end of the pivotable link 121. In this case, the first shaft member protruding from the pivotable link 121 is inserted into the lower body 111, so that the pivotable link 121 is rotatably coupled to the lower body 111.

In this case, a locking elastic member (not shown) for switching the pivotable link 121 to a locked state in the absence of an external force may be mounted on the first shaft member functioning as the rotation axis of the pivotable link 121. As one example, the locking elastic member may be provided in the form of a coil spring wound around the first shaft member, and may provide elastic force to the first shaft member and/or the pivotable link 121 in a direction that maintains the pivotable link 121 in the locked state.

The fixing member 122 is coupled to the distal end of the pivotable link 121 in an angle-adjustable manner and selectively presses the semiconductor product D according to the angle of the pivotable link 121. That is, the fixing member 122 presses the semiconductor product D when the pivotable link 121 is switched to the locked state. A mounting hole parallel to the link hole may be formed at the distal end of the pivotable link 121. A second shaft member functioning as the rotation axis of the fixing member 122 may be inserted into the mounting hole. The second shaft member protruding from the mounting hole is inserted into the fixing member 122, so that the fixing member 122 may be coupled to the other end of the pivotable link 121 in an angle-adjustable manner. Alternatively, the second shaft member may protrude from the fixing member 122.

In this regard, similar to the first shaft member, a fixing elastic member (not shown) may also be mounted on the second shaft member. The fixing elastic member may provide an elastic force to the fixing member 122 in a direction toward the semiconductor product D in a state in which the fixing member 122 is in contact with the semiconductor product D. Referring to FIG. 7, in the locked state, the fixing member 122 is superimposed on the upper surface of the semiconductor product D, and the fixing elastic member provides elastic force in a direction in which the fixing member 122 is brought into close contact with the semiconductor product D. Accordingly, the locking elastic member and the fixing elastic member may provide elastic force in the same direction. As one example, the fixing elastic member may be implemented in a form similar to a coil spring wound around the second shaft member that applies elastic force to the fixing member 122.

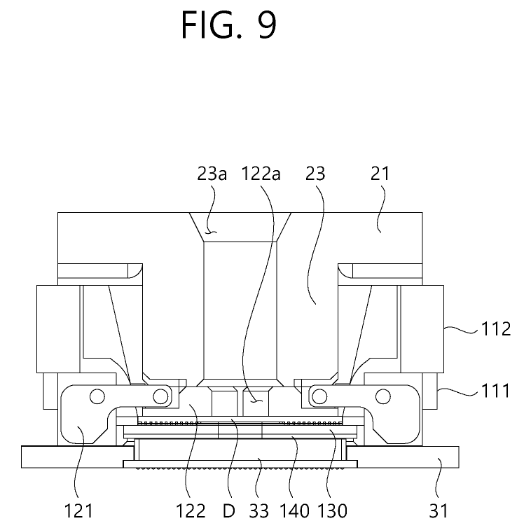

Since the fixing member 122 is rotatably coupled to the pivotable link 121, according to the present disclosure, even if the height of the semiconductor product D varies somewhat, the fixing member 122 may always be brought into close contact with the semiconductor product D in a parallel posture. In this case, since the fixing member 122 is implemented as a flat plate-shaped member, in a state of fixing the semiconductor product D, the fixing member 122 may press the entire upper surface of the semiconductor product D. In addition, the upper surface of the fixing member 122 exposed to the loading space 110a becomes parallel to the semiconductor product D. This has the effect of making it easier to distribute the force across the entire upper surface of the semiconductor product D when the contact pusher presses the fixing member 122. The description of this will be given later with reference to FIGS. 9 and 10.

In this regard, the free end of the fixing member 122 may be concavely recessed. For example, the center of the distal end of the fixing member 122 may be recessed in approximately a semicircular shape toward the pivotable link 121. As a result, in the locked state, an exposure hole 122a is defined between a pair of fixing members 122 facing each other, positioned above the central portion of the semiconductor product D. The exposure hole 122a may be an approximately cylindrical space defined by the space between the pair of fixing members 122 in the locked state. The central portion of the semiconductor product D may be exposed to the loading space 110a via the exposure hole 122a.

Referring to FIG. 5, the upper body 112 may be formed with an accommodation groove 112a into which a portion of the pivotable link 121 and the fixing member 122 in the open state may be accommodated. The accommodation groove 112a is formed by recessing the side wall of the upper body 112 so that portions of the pivotable link 121 and the fixing member 122 may be accommodated during the process of switching from the locked state to the open state.

The principle under which the angle of the pivotable link 121 is adjusted according to the raising and lowering of the upper body 112 may be as follows. For example, the upper body 112 may press one end of the pivotable link 121 as it descends. Specifically, the upper body 112 descends and presses the end of the pivotable link 121 located on the opposite side from the fixing member 122. In this regard, the rotation axis of the pivotable link 121 is located between the area pressed by the upper body 112 and the fixing member 122. Accordingly, the pressing of the pivotable link 121 by the upper body 112 causes the angular motion of the pivotable link 121. When the upper body 112 is fully lowered, the pivotable link 121 defines an angle approximately perpendicular to the precision-contact interposer 130.

In this regard, although not shown, between the upper body 112 and the lower body 111, an insert elastic member may be disposed that provides elastic force to position the upper body 112 at the maximum height in the absence of an external force. As a result, in the absence of an external force, the upper body 112 is positioned at the maximum height, and the fixing latch 120 may maintain a locked state as shown in FIG. 5. For example, the insert elastic member may be a coil spring.

In the above examples, the various elastic members have been described as coil springs by way of example; however, the present disclosure is not limited thereto. That is, the various elastic members mounted in the present disclosure are not limited in form as long as they may provide elastic force in the direction described in the foregoing description.

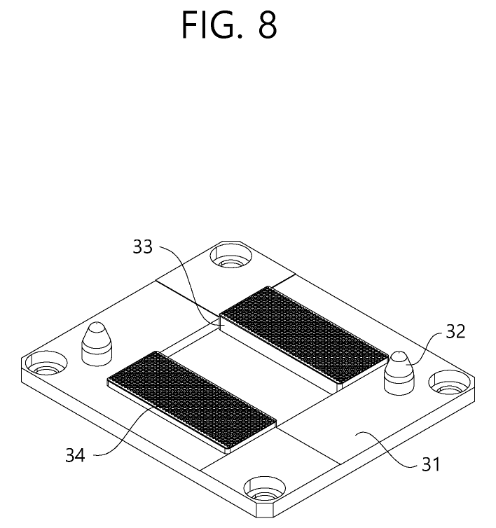

Hereinafter, with reference to FIG. 8, the socket in which the carrier according to an embodiment of the present disclosure is seated is described. FIG. 8 is a drawing for illustrating a socket in which a carrier according to an embodiment of the present disclosure is seated.

As shown in FIG. 8, the socket 30 in which the carrier is seated may include a socket guide 31 and a contact pad 33. The socket guide 31 is a plate that guides the seating position of the insert body. To guide the seating position of the insert body, at least one guide pin 32 protrudes upward from the upper surface of the socket guide 31. The guide pin 32 may adjust the position of the insert body by being inserted into the lower body as the insert body is seated on the socket guide 31.

The contact pad 33 is the portion where the contact points 34 that contact the socket contacting part are formed. The contact points 34 may be implemented by various conventionally known electrical connection means. For example, the contact points 34 of the contact pad 33 may be pogo pins or MEMS pins. Alternatively, the contact pad 33 may be implemented as a rubber socket and the contact points 34 may be implemented with a conductive material. The contact pad 33 is electrically connected to the motherboard of the test apparatus. Accordingly, the semiconductor product and the test apparatus exchange signals through the contact points 34.

Hereinafter, with reference to FIGS. 9 and 10, the mounting test using the carrier according to an embodiment of the present disclosure is described. FIG. 9 is a cross-sectional view of a state in which a mounting test is performed using a carrier according to an embodiment of the present disclosure. In contrast, FIG. 10 is a drawing conceptually representing a state in which a mounting test is performed using a carrier according to an embodiment of the present disclosure. In this regard, in FIG. 10, the device terminals B are illustrated in the form of solder balls for convenience; however, the test target of the present disclosure is not limited to such examples.

Referring to FIGS. 9 and 10, the mounting test is performed in a state in which the pressing protrusion 23 presses the fixing member 122. The operation of pressing the fixing member 122 enhances the close contact between the semiconductor product D and the precision-contact interposer 130, allowing the device terminals B and the upper terminals 131a to contact more reliably. In this regard, as previously described, since the fixing member 122 is implemented like a plate shape with flat upper and lower surfaces, it is possible to uniformly distribute and transmit the external force by the pressing protrusion 23 to the upper surface of the semiconductor product D. In this regard, the cover pad 132 prevents excessive pressure from being applied to the semiconductor product D and the circuit board 131. For example, the cover pad 132 may be compressed in portions where the pressure is locally large, absorbing a portion of the external force, thereby inducing a uniform load distribution to be formed on the circuit board 131 and the semiconductor product D.

In this regard, in a state in which the pressing protrusion 23 presses the fixing member 122, the gas passage 23a and the exposure hole 122a are aligned coaxially. Accordingly, the gas injected through the gas passage 23a is discharged toward the central portion of the semiconductor product D, and the semiconductor product D exchanges heat with the discharged gas, and thus its temperature is regulated.

Hereinafter, the electrical connection path between the semiconductor product D and the contact pad 33 is described. During the process in which equipment such as a picker places the semiconductor product D on the precision-contact interposer 130, the position of the semiconductor product D is adjusted by the guide film 133. As a result, the device terminals B are aligned above the upper terminals 131a. In this regard, the upper terminals 131a are electrically connected to the lower terminals 131b through the circuitry formed inside the circuit board 131. In addition, the lower terminals 131b are in contact with the upper end of the contact terminals 140a. After the semiconductor product D is placed in the correct position, the state of the fixing member 122 is switched from the open state to the locked state, and the position of the semiconductor product D is fixed. The semiconductor product D is then transported to the test apparatus by a separate transport device. After the carrier is transported to the test apparatus, the transport device places the lower body 111 on the socket guide 31. During the process of the lower body 111 being seated on the upper surface of the socket guide 31, the seating position of the lower body 111 is guided by the guide pins. When the lower body 111 is fully seated in the socket guide 31, the contact terminals 140a and the contact points 34 come into contact. As a result, the device terminals B are electrically connected to the contact points 34 through the upper terminals 131a, the internal circuitry of the circuit board 131, the lower terminals 131b, and the contact terminals 140a.

In this way, according to the present disclosure, once the semiconductor product D is loaded into the carrier and the semiconductor product D and the upper terminals 131a are aligned once, the semiconductor product D is fixed in the aligned state, and the additional precision alignment work may be omitted. In addition, according to the present disclosure, when the picker presses the upper body 112 while placing the semiconductor product D, the fixing latch 120 naturally opens, and when the picker rises after placing the semiconductor product D, the upper body 112 rises again and the fixing latch 120 is switched to the locked state, so that the semiconductor product D may be immediately fixed in succession to the precise placing operation.

In addition, according to the present disclosure, since the circuit board 131 and the contact pad 33 do not directly contact each other but contact each other via the socket contacting part 140, damage to the circuit board 131 may be minimized while performing repeated tests.

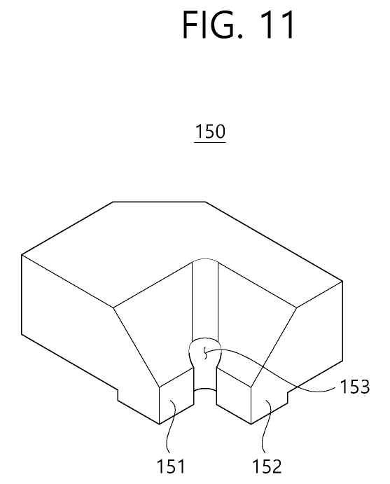

Hereinafter, with reference to FIG. 11, the guide member according to an embodiment of the present disclosure is described. FIG. 11 is a drawing illustrating a guide member according to an embodiment of the present disclosure.

As shown in FIG. 11, the guide member 150 according to an embodiment of the present disclosure has a shape bent at approximately a right angle. This is a shape corresponding to the edge of the semiconductor product. That is, the guide member 150 has a shape that simultaneously contacts two adjacent surfaces of the semiconductor product while pushing it. For convenience of illustration, hereinafter, the surface contacting one surface of the semiconductor product is referred to as a first contact surface 151, and the surface contacting the other surface is referred to as a second contact surface 152.

Between the first contact surface 151 and the second contact surface 152 of the guide member 150, a contact-prevention groove 153 is formed. The contact-prevention groove 153 extends along the height direction of the guide member 150 between the first contact surface 151 and the second contact surface 152. Therefore, in a state in which the first contact surface 151 and the second contact surface 152 are in contact with two adjacent surfaces of the semiconductor product, the edge where the two surfaces of the semiconductor product meet is accommodated in the contact-prevention groove 153. The contact-prevention groove 153 may prevent damage to the semiconductor product by preventing contact between the corner portion of the semiconductor product, which is vulnerable to stress, and the guide member 150.

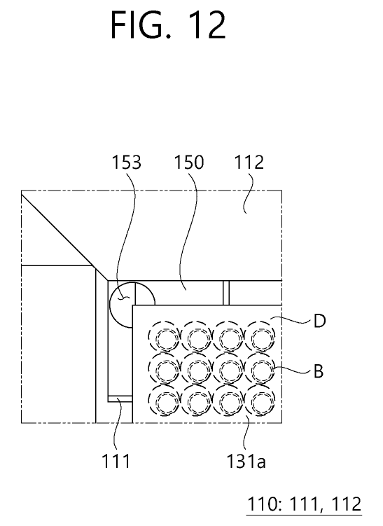

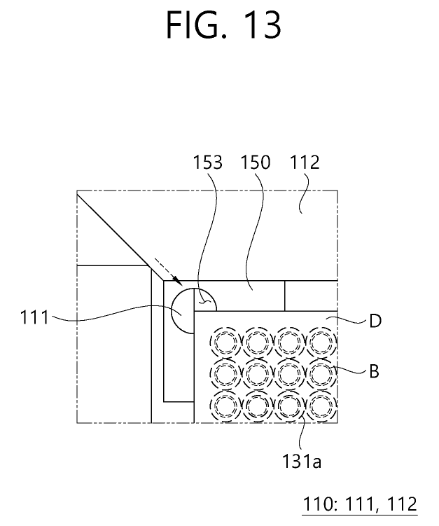

Hereinafter, with reference to FIGS. 12 and 13, the positional alignment function of the semiconductor product D by the guide member 150 is described.

FIG. 12 is a drawing representing a state in which a guide member according to an embodiment of the present disclosure is accommodated to a maximum extent inside the insert body. In contrast, FIG. 13 is a drawing representing a state in which a guide member according to an embodiment of the present disclosure protrudes to a maximum extent outside the insert body.

As shown in FIGS. 12 and 13, the guide member 150 is mounted to the insert body 110 such that at least a portion thereof may protrude from and retract into the side wall of the insert body 110. Specifically, the guide member 150 may be installed to protrude from and retract into the insert body 110 by utilizing the space created by the gap between the upper body 112 and the lower body 111. In addition, the height of the guide member 150 is set to be positioned laterally to the semiconductor product D seated on the precision-contact interposer.

When the semiconductor product D is first loaded into the insert body 110, the state may be as shown in FIG. 12. In the state of FIG. 12, the semiconductor product D is not seated in the perfect position, so the device terminals B and the upper terminals 131a are out of alignment. In this regard, when the guide member 150 according to an embodiment of the present disclosure is used, it is possible for the guide member 150 to protrude as shown in FIG. 13, pushing the semiconductor product D toward the correct position. When pushed by the guide member 150 and the position is adjusted, the device terminals B and the upper terminals 131a may be aligned as shown in FIG. 13. For example, the protrusion distance of the guide member 150 may be set to a distance such that when the guide member 150 is maximally protruded and pushes the semiconductor product D accommodated in the loading space to a maximum extent, the device terminals B and the upper terminals 131a are aligned.

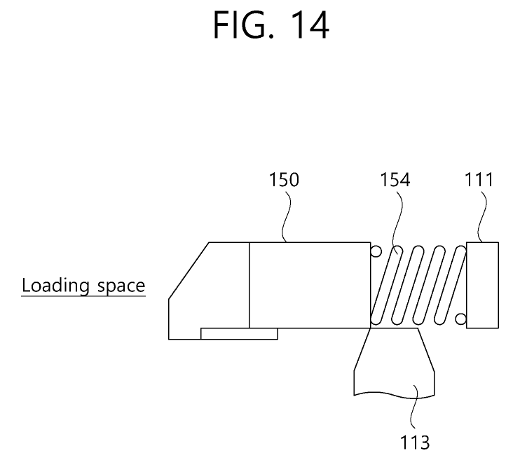

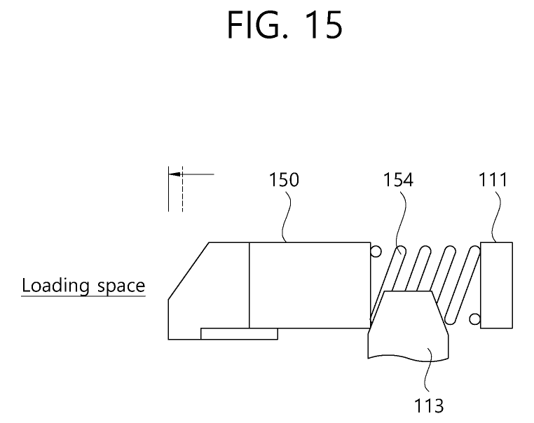

Hereinafter, with reference to FIGS. 14 and 15, the structure implementing the operation of the guide member 150 according to an embodiment of the present disclosure is described. FIG. 14 is a drawing representing the state of the guide member in the same state as FIG. 12. In contrast, FIG. 15 is a drawing representing the state of the guide member in the same state as FIG. 13.

As shown in FIGS. 14 and 15, the operation of the guide member 150 according to an embodiment of the present disclosure is implemented by an open-maintaining elastic member 154 and a pressing member 113.

Specifically, the open-maintaining elastic member 154 provides an elastic force to the guide member 150 in a direction away from the loading space. To this end, the open-maintaining elastic member 154 may have one end connected to the guide member 150 and the other end connected to the lower body 111. Accordingly, in the absence of an external force, the guide member 150 may be brought into maximum contact with the side wall of the lower body 111 by the open-maintaining elastic member 154. As one example, the open-maintaining elastic member 154 may be provided as a coil spring or as a conventionally known elastic member capable of performing a similar function.

In this regard, the pressing member 113 may be an approximately pin-shaped component connected to the upper body 112 (see FIG. 2). Accordingly, the pressing member 113 may be raised and lowered together with the upper body 112. When the upper body 112 is at the lowest height, the pressing member 113 may be positioned under the rear of the guide member 150. That is, when the upper body 112 is at the lowest height, the pressing member 113 is positioned under the area where the open-maintaining elastic member 154 and the guide member 150 are connected. When the upper body 112 rises, the pressing member 113 moves toward the guide member 150 and, using the force by which the upper body 112 rises, overcomes the elastic force of the open-maintaining elastic member 154 and advances the guide member 150 toward the loading space. For the advancement of the guide member 150 to proceed smoothly, the pressing member 113 may have an inclined surface that starts from the upper end and becomes closer to the loading space direction as the height decreases.

That is, the pressing member 113 may push the guide member 150 forward while rising together with the upper body 112. When the upper body 112 is maximally lowered, the pressing member 113 waits below the rear of the guide member 150 as shown in FIG. 14. Thereafter, when the upper body 112 rises, the pressing member 113 rises together with the upper body 112 and advances the guide member 150 as shown in FIG. 15.

When the guide member 150 operates in this manner, there is the advantage that the guiding action by the guide member 150 and the fixing action by the fixing latch 120 (see FIG. 2) are performed consecutively. Specifically, when the upper body 112 is maximally lowered and the fixing latch 120 is in the open state, the guide member 150 is accommodated to a maximum extent in the insert body 110 as shown in FIG. 12. Thereafter, when the semiconductor product is loaded into the insert and the upper body 112 rises, the guide member 150 first advances by the pressing member 113, and then the fixing latch 120 consecutively fixes the semiconductor product.

Therefore, when using the guide member 150, it is sufficient to place the semiconductor product only in a position where it may be aligned by the guide member 150 during the initial loading process, thereby saving the time required for precisely placing the semiconductor product.

Those skilled in the art to which the present disclosure pertains will understand that the present disclosure may be implemented in other specific forms without changing its technical spirit or essential features. Therefore, the embodiments described above should be understood as illustrative in all respects and not restrictive. The scope of the present disclosure is indicated by the following claims rather than the detailed description above, and all changes or modifications derived from the meaning and scope of the claims and the concept of equivalents thereof should be construed as being included within the scope of the present disclosure.

### REFERENCE NUMERALS

1: carrier; 10: insert; 20: contact pusher; 21: cover plate; 22: insertion pin; 23: pressing protrusion; 23a: gas passage; 30: socket; 110: insert body; 111: lower body; 112: upper body; 113: pressing member; 120: fixing latch; 121: pivotable link; 122: fixing member; 130: precision-contact interposer; 131: circuit board; 132: cover pad; 133: guide film; 140: socket contacting part; 150: guide member; 154: open-maintaining elastic member

What is claimed is:

1. A carrier for a fine-pitch semiconductor product, comprising:
an insert body providing a loading space in which a semiconductor product is accommodated;
a precision-contact interposer defining a bottom of the loading space, wherein the precision-contact interposer has a plurality of upper terminals upwardly exposed from an upper surface thereof so as to be in contact with device terminals of the semiconductor product accommodated in the loading space, and a plurality of lower terminals electrically connected to the upper terminals and downwardly exposed from a lower surface thereof, wherein a spacing between the lower terminals is larger than a spacing between the upper terminal; and
a socket contacting part positioned under the precision-contact interposer, wherein the socket contacting part in lieu of the precision-contact interposer is brought into close contact with a socket of a test apparatus, wherein the socket contacting part has a plurality of contact terminals electrically connecting contact points of the socket with the lower terminals.

2. The carrier for the fine-pitch semiconductor product of claim 1, wherein the precision-contact interposer comprises a circuit board having the lower terminals formed on a lower surface thereof and the upper terminals formed on an upper surface thereof, wherein the upper terminals have minute sizes and arrangement spacings corresponding to minute sizes and arrangement spacings of the device terminals.

3. The carrier for the fine-pitch semiconductor product of claim 2, wherein the precision-contact interposer further comprises a cover pad disposed on top of the circuit board so as to protect the device terminals and the circuit board during a process of bringing the semiconductor product and the circuit board into contact with each other, wherein the cover pad includes an elastic material and has a plurality of pad holes extending therethrough to expose the upper terminals.

4. The carrier for the fine-pitch semiconductor product of claim 3, wherein the precision-contact interposer further comprises a guide film disposed on top of the cover pad and having guide holes formed therein and aligned above the pad holes, wherein the guide film includes an elastic material and thus guides the device terminals approaching the circuit board toward the pad holes base on an elastic force.

5. The carrier for the fine-pitch semiconductor product of claim 2, wherein the precision-contact interposer further comprises a cover pad disposed on top of the circuit board so as to protect the device terminals and the circuit board during a process of bringing the semiconductor product and the circuit board into contact with each other, wherein the cover pad includes an elastic material and has conductive materials disposed between the upper terminals and the device terminals.

6. The carrier for the fine-pitch semiconductor product of claim 2, wherein the circuit board comprises a glass substrate.

7. The carrier for the fine-pitch semiconductor product of claim 1, wherein an observation hole extending through the precision-contact interposer and the socket contacting part is formed to observe the semiconductor product accommodated in the loading space.

8. The carrier for the fine-pitch semiconductor product of claim 1, wherein the precision-contact interposer is constructed so as to be replaceable separately from the socket contacting part so that a plurality types of semiconductor products can be tested using a single test apparatus.

9. The carrier for the fine-pitch semiconductor product of claim 1, further comprising a guide member mounted to the insert body in a horizontally reciprocating manner so as to laterally push the semiconductor product accommodated in the loading space.

10. The carrier for the fine-pitch semiconductor product of claim 9, wherein the guide member is mounted to the insert body such that at least a portion thereof can move toward or away from a side wall of the insert body.

11. The carrier for the fine-pitch semiconductor product of claim 9, wherein the guide member is formed in a shape capable of contacting two surfaces of the semiconductor product meeting each other in a process of pushing the semiconductor product.

12. The carrier for the fine-pitch semiconductor product of claim 9, wherein the device terminals and the upper terminals are aligned with each other in a state in which the guide member has pushed the semiconductor product accommodated in the loading space to a maximum extent.

13. The carrier for the fine-pitch semiconductor product of claim 9, further comprising:
an open-maintaining elastic member constructed to provide an elastic force to the guide member such that the guide member moves away from the loading space; and
a pressing member constructed to receive an external force to move toward the guide member to overcome the elastic force of the open-maintaining elastic member to move the guide member toward the loading space.

14. The carrier for the fine-pitch semiconductor product of claim 13, wherein the insert body comprises:
a lower body to which the precision-contact interposer and the socket contacting part are coupled; and
an upper body coupled to an upper side of the lower body in a liftable manner, wherein the upper body surrounds the loading space, and has an open upper surface,
wherein the pressing member is connected to the upper body and is constructed to move the guide member while the pressing member moves vertically together with the upper body.

15. The carrier for the fine-pitch semiconductor product of claim 14, further comprising a fixing latch having a first end coupled to the lower body in an angle-adjustable manner, and constructed such that an angle thereof is adjusted along with the upper body moving vertically,
wherein in a state in which the upper body has been maximally raised, a second end of the fixing latch downwardly presses the semiconductor product accommodated in the loading space while being positioned on top of the semiconductor product,
wherein while the upper body is descending, the pressing member retracts downwards while being positioned in rear of the guide member,
wherein while the upper body is ascending, the pressing member moves upwardly to move the guide member while being positioned in rear of the guide member.

16. The carrier for the fine-pitch semiconductor product of claim 1, further comprising a fixing latch coupled to the insert body in an angle-adjustable manner to selectively fix the semiconductor product accommodated in the loading space.

17. The carrier for the fine-pitch semiconductor product of claim 16, wherein the fixing latch comprises:
a pivotable link having a first end coupled to the insert body in an angle-adjustable manner; and
a fixing member constructed to selectively press the semiconductor product based on the angle of the pivotable link, wherein the fixing member is coupled to a second end of the pivotable link in an angle-adjustable manner.

18. The carrier for the fine-pitch semiconductor product of claim 17, wherein the fixing latch further comprises a fixing elastic member constructed to provide an elastic force acting toward the semiconductor product to the fixing member in a state in which the fixing member is in contact with the semiconductor product.

19. The carrier for the fine-pitch semiconductor product of claim 17, further comprising a contact pusher removably mounted onto an upper side of the insert body, wherein in a mounted state thereon, the contact pusher presses the fixing member downwards.

20. The carrier for the fine-pitch semiconductor product of claim 17, wherein the fixing latch includes a pair of fixing latches coupled to the insert body and facing each other,
wherein an end portion of the fixing member is concavely recessed so that, in a state
in which the pair of fixing latches has fixed the semiconductor product, a central area of the semiconductor product is exposed to an outside.
